(19) United States
(12) Patent Application Publication
(10) Pub. No.: US 2008/0284489 A1
(43) Pub. Date: Nov. 20, 2008

(54) TRANSCONDUCTOR AND MIXER WITH HIGH LINEARITY

(75) Inventor: Eng Chuan Low, Dover Crescent (SG)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK SINGAPORE PTE LTD, Ayer Rajah Crescent (SG)

(21) Appl. No.: 11/748,014

(22) Filed: May 14, 2007

(51) Int. Cl. H03F 3/189

(52) U.S. Cl. 327/359

(57) ABSTRACT

A transconductor. The transconductor comprises first and second active device networks. The first active device network has a first node and a second node and comprises a first MOS transistor having a gate, a source coupled to the first node, and a drain coupled to the second node. The second active device network has a first node and a second node respectively connected to the first and second nodes of the first active device network and comprises a second MOS transistor and a voltage drop generator. The second MOS transistor has a gate and a source respectively connected to the gate and the source of the first MOS transistor. The voltage drop generator is coupled between a drain of the second MOS transistor and the second nodes of the first and second active device networks and generates a voltage drop across the same.

### BACKGROUND OF THE INVENTION

1. Field of the Invention

The invention relates to a transconductor and a mixer circuit and, in particular, to a transconductor and a mixer circuit with improved linearity.

2. Description of the Related Art

Mixer circuits for high frequency applications constructed using metal oxide semiconductor (MOS) transistors are subject to a limited voltage supply (usually less than 2V) and high levels of flicker noise, having frequencies extending up to several tens of MHz. Accordingly, the gain and output signal level required in such mixer circuits exceed those required in the equivalent bipolar circuits.

FIG. 1 is a circuit diagram illustrating a conventional double balanced mixer circuit disclosed in U.S. Pat. No. 6,636,115. The double balanced mixer circuit of FIG. 1 includes differential pairs of MOSFETs (Q131-Q132 and Q133-Q134). The drains of the pairs of MOSFETs are connected to an output terminal (Output-I⁺ and Output-I⁻). The gates of the pairs of MOSFETs are connected to first input terminals (Input-II⁺ and Input-II⁻). The double balanced mixer circuit in FIG. 1 also includes active devices Q135, Q136, Q137 and Q138. The sources of the MOSFET pair Q131-Q132 are connected to the drains of the active devices Q135 and Q136. The sources of the MOSFET pair Q133-Q134 are connected to the drains of the active devices Q137 and Q138. The gates of the active devices Q135, Q136, Q137 and Q138 are connected to the second input terminal (Input-I⁺ and Input-I⁻) through input side biasing and matching circuits (Bias Network-I, Bias Network-II, Bias Network-III and Bias Network-IV, respectively). The sources of the active devices Q135, Q136, Q137 and Q138 are connected to the ground through an impedance unit (Degeneration Impedance) and Bias Network-V.

Two separate bias networks (Bias Network-I and Bias Network-II) are respectively provided for the MOSFETs Q135 and Q-136 such that gate to source bias voltages (Vgs) thereof are different. Due to the different gate to source bias voltages (Vgs), the MOSFETs Q135 and Q-136 respectively operate in a saturation region and a sub-threshold region. However, accuracy of device model [symbol] Fab [symbol] SPICE model [symbol] sub-threshold region [symbol] device model [symbol] [symbol] sub-threshold region [symbol] [symbol] in sub-threshold region is limited, increasing difficulty in circuit design. In addition, non-linearity cancellation is such that the circuit is limited to a small gate to source bias voltage (Vgs) range

[symbol]

[symbol]

[symbol]

### BRIEF SUMMARY OF THE INVENTION

An embodiment of a transconductor comprises first and second active device networks. The first active device network has a first node and a second node and comprises a first MOS transistor having a gate, a source coupled to the first node, and a drain coupled to the second node. The second active device network has a first node and a second node respectively connected to the first and second nodes of the first active device network and comprises a second MOS transistor and a voltage drop generator. The second MOS transistor has a gate and a source respectively connected to the gate and the source of the first MOS transistor. The voltage drop generator is coupled between a drain of the second MOS transistor and the second nodes of the first and second active device networks and generates a voltage drop across the same.

An embodiment of a mixer circuit comprises a transconductor, a Gilbert cell mixer core, and a pair of resistors. The transconductor comprises first and second active device networks. The first active device network has a first node and a second node and comprises a first MOS transistor having a gate, a source coupled to the first node, and a drain coupled to the second node. The second active device network has a first node and a second node respectively connected to the first and second nodes of the first active device network and comprises a second MOS transistor and a voltage drop generator. The second MOS transistor has a gate and a source respectively connected to the gate and the source of the first MOS transistor. The voltage drop generator is coupled between a drain of the second MOS transistor and the second nodes of the first and second active device networks and generates a voltage drop across the same. The gates of the first and second MOS transistors receive a first differential input signal and the first nodes of the first and second active device networks are coupled to a first supply voltage. The Gilbert cell mixer core receives a second differential input signal and has third nodes coupled to the second nodes of the first and second active device networks and fourth nodes providing a differential output signal. The resistors are respectively coupled between the fourth nodes of the Gilbert cell mixer core and a second supply voltage.

The invention provides a transconductor and a mixer circuit comprising first and second active device networks. MOS transistors in the first and second active device networks respectively operate in a triode region and a saturation region and non-linearity induced by the MOS transistors is thus cancelled.

A detailed description is given in the following embodiments with reference to the accompanying drawings.

### BRIEF DESCRIPTION OF THE DRAWINGS

The invention can be more filly understood by reading the subsequent detailed description and examples with references made to the accompanying drawings, wherein:

FIG. 1 is a circuit diagram illustrating a conventional double balanced mixer circuit disclosed in U.S. Pat. No. 6,636,115; and

FIGS. 2A and 2B are respectively a schematic diagram and a circuit diagram of a double balanced mixer circuit according to an embodiment of the invention;

FIGS. 2C and 2D show embodiments of the voltage drop generator VDG in FIG. 2B;

FIG. 3A is a circuit diagram of a double balanced mixer circuit according to another embodiment of the invention;

FIG. 3B is a circuit diagram of a variant of the double balanced mixer circuit in FIG. 2B;

FIG. 3C is a circuit diagram of a variant of the double balanced mixer circuit in FIG. 3A.

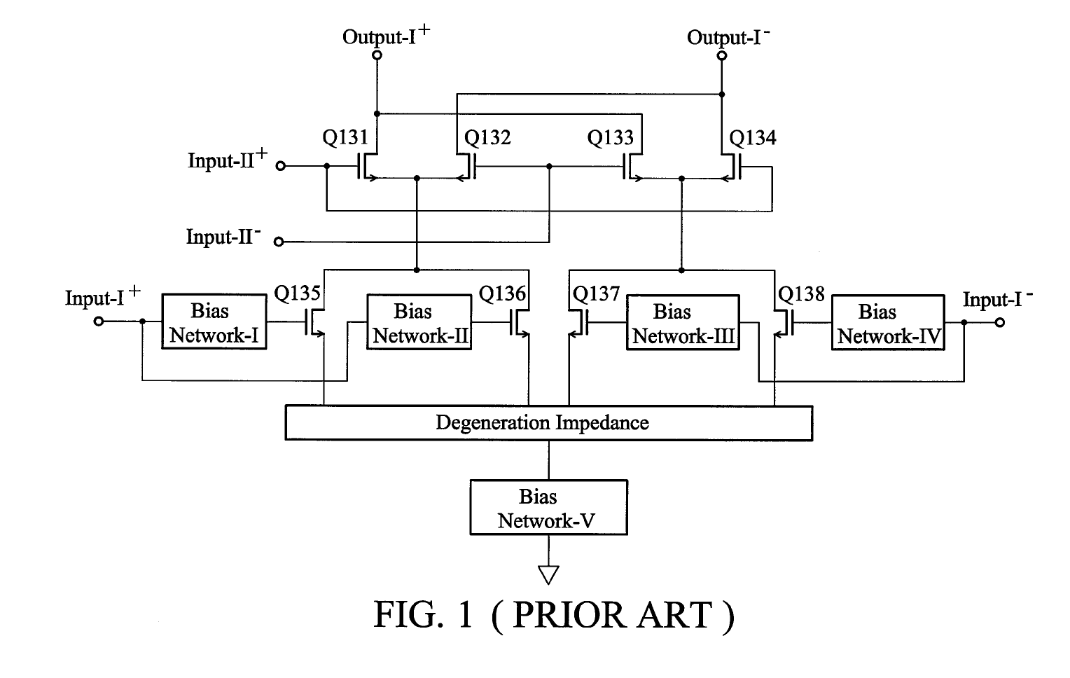

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

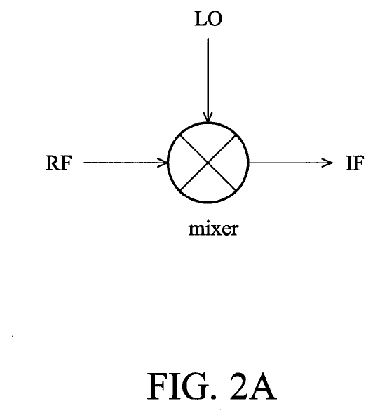

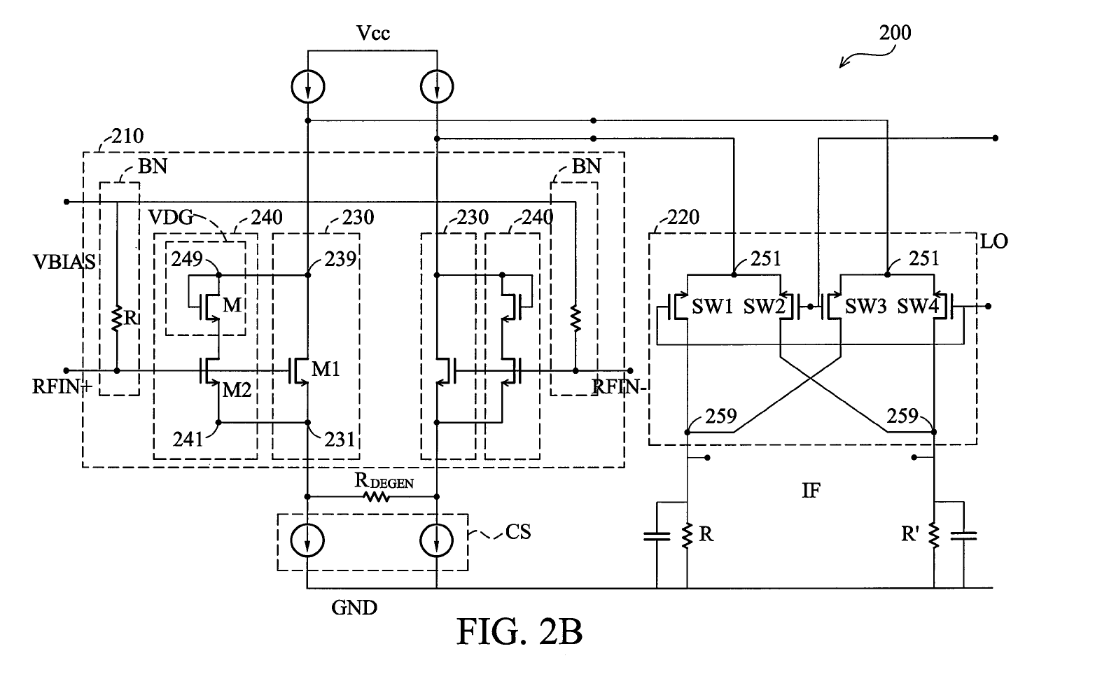

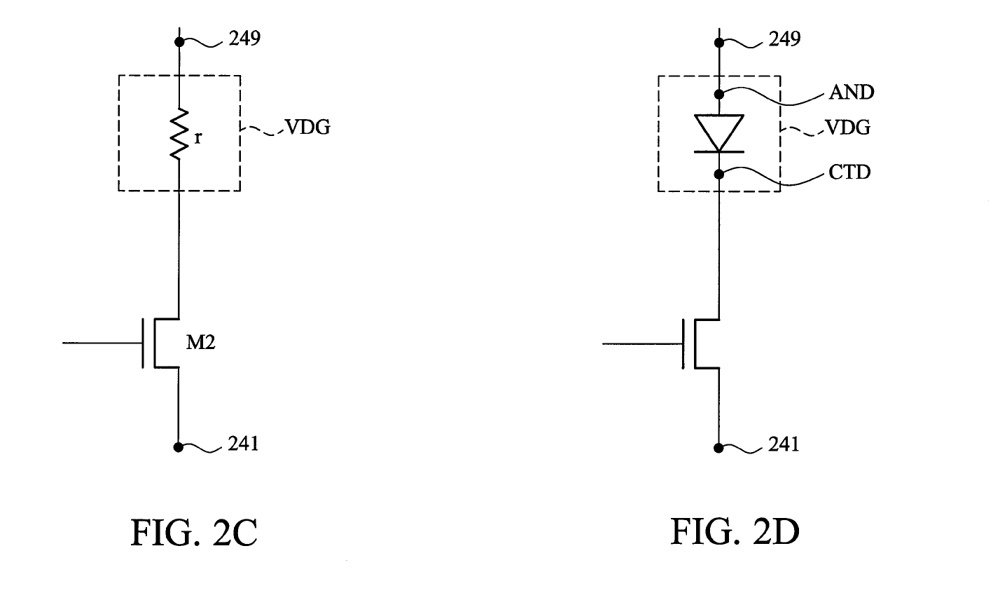

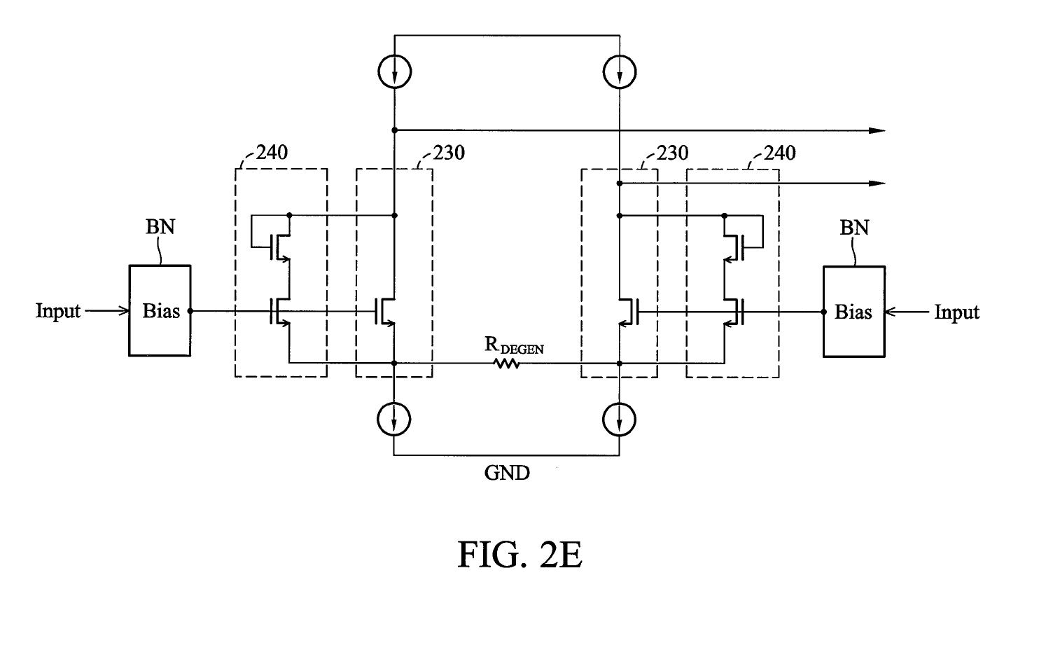

FIGS. 2A and 2B are respectively a schematic diagram and a circuit diagram of a double balanced mixer circuit according to an embodiment of the invention. The double balanced mixer circuit 200 comprises a transconductor 210, a Gilbert cell mixer core 220, and a pair of resistors R and R′. [symbol] The transconductor 210 comprises first active device network 230 and a second active device network 240. The first active device network 230 has a first node 231 and a second node 239. The first active device network 230 comprises a first MOS transistor M1 having a gate, a source coupled to the first node 231, and a drain coupled to the second node 239. The second active device network 240 has a first node 241 and a second node 249 respectively connected to the first node 231 and second node 239 of the first active device network 230. The second active device network 240 comprises a second MOS transistor M2 and a voltage drop generator VDG. The second MOS transistor M2 has a gate and a source respectively connected to the gate and the source of the first MOS transistor M1. The voltage drop generator VDG is coupled between a drain of the second MOS transistor M2 and the second nodes 239 and 249 of the first and second active device networks 230 and 240. A voltage drop is generated across the voltage drop generator VDG. More specifically, the voltage drop generator VDG is a diode-connected MOS transistor with a source thereof connected to the drain of the second MOS transistor M2 and a gate and a drain thereof connected to the second node 249 of the second active device network 240. The gates of the first and second MOS transistors MI and M2 receive a first differential input signal RFIN+/RFIN−. The first nodes 231 and 241 of the first and second active device networks 230 and 240 are coupled to a first supply voltage. More specifically, the first supply voltage is a ground GND. The Gilbert cell mixer core 220 receives a second differential input signal LO and has third nodes 251 coupled to the second nodes 239 and 249 of the first and second active device networks 230 and 240. A differential output signal IF is provided at the fourth nodes 259 of the Gilbert cell mixer core 220. The resistors R and R′ [symbol] ) are respectively coupled between the fourth nodes of the Gilbert cell mixer core 220 and a second supply voltage. Preferably, the first supply voltage and the second supply voltage are the same. In the embodiment, the first and second supply voltage is a ground GND.

In FIG. 2B, the Gilbert cell mixer core 220 comprises differential pairs of P-type MOSFETs (SW1-SW2 and SW3-SW4). The drains of the pairs of MOSFETs are connected to the fourth nodes 259 of the Gilbert cell mixer core 220. The gates of the pairs of MOSFETs receive the second differential input signal LO. The sources of the MOSFET pair SW1-SW2 are connected to the third nodes 251 of the Gilbert cell mixer core 220. The sources of the MOSFET pair SW3-SW4 are also connected to the third nodes 251 of the Gilbert cell mixer core 220. In addition, a degeneration impedance RDEGEN is coupled between the first supply voltage and the transconductor 210. A bias network (current sources) CS is coupled between the first supply voltage and the transconductor 210. Furthermore, a bias network BN (resistor R) provides a bias voltage to the first and second MOS transistors M1 and M2. Since a voltage drop is generated across the voltage drop generator VDG, the first MOS transistor M1 operates in a saturation region and the second MOS transistor M2 in a triode region. As a result, non-linearity induced by the first and second MOS transistors is thus cancelled.

FIG. 2C and 2D [symbol] ) shows embodiments of the voltage drop generator VDG in FIG. 2B. In FIG. 2C, the voltage drop generator VDG is a resistor r coupled between the drain of the second MOS transistor M2 and the second nodes 239 and 249 of the first and second active device networks 230 and 240. In FIG. 2D, the voltage drop generator VDG is a diode D with an anode AND coupled to the second nodes 239 and 239 of the first and second active device networks 230 and 240 and a cathode CTD coupled to the drain of the second MOS transistor M2.

FIG. 2E is a simplified circuit diagram of the double balanced mixer circuit in FIG. 2B. In FIG. 2E, bias voltages of the first and second MOS transistors 230 and 240 are provided by the same bias network BN and the double balanced mixer circuit is simpler than a conventional one.

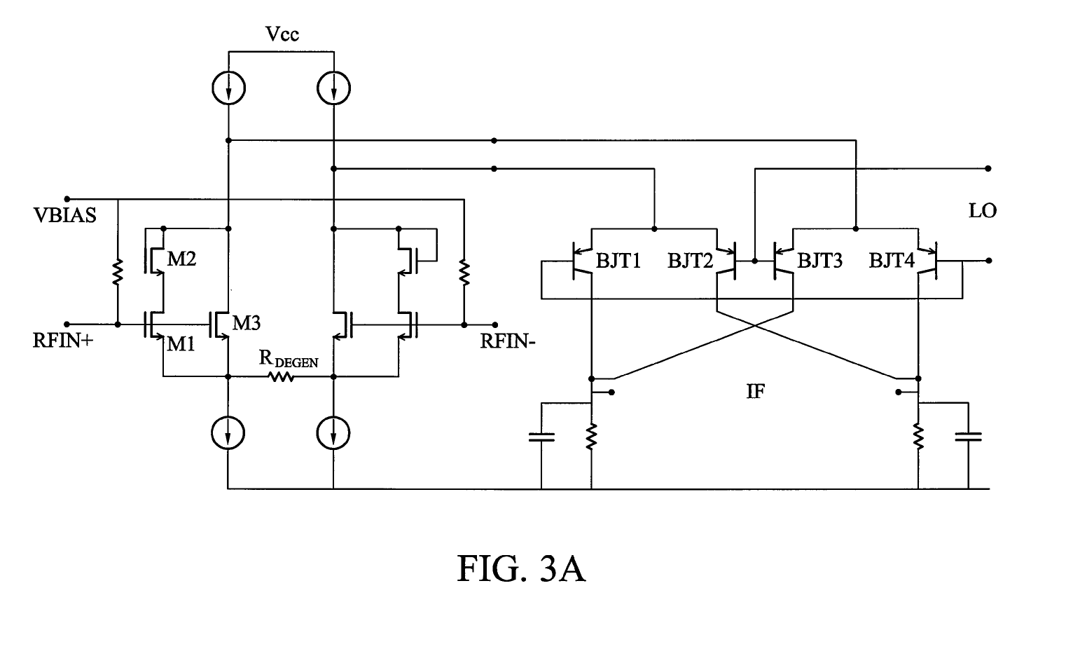

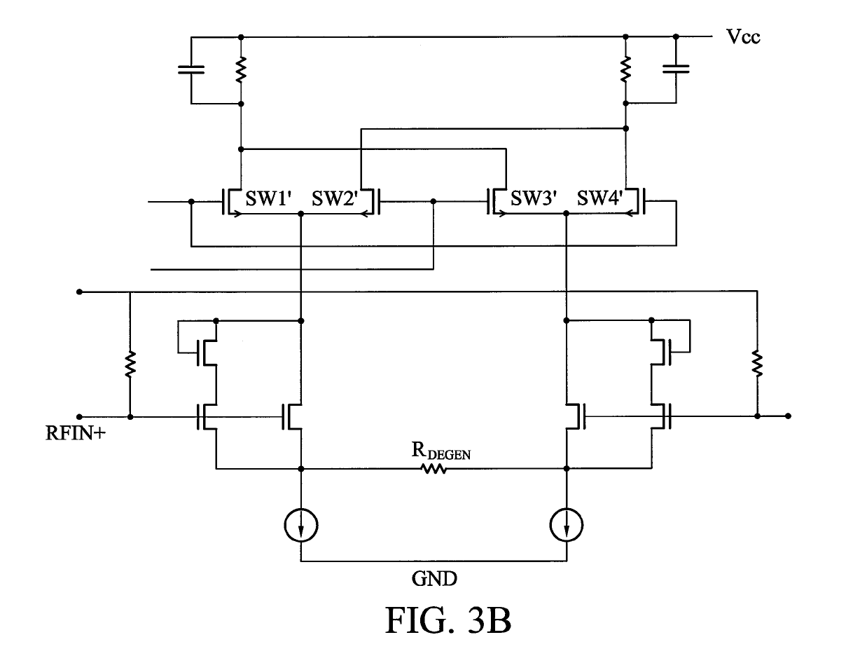

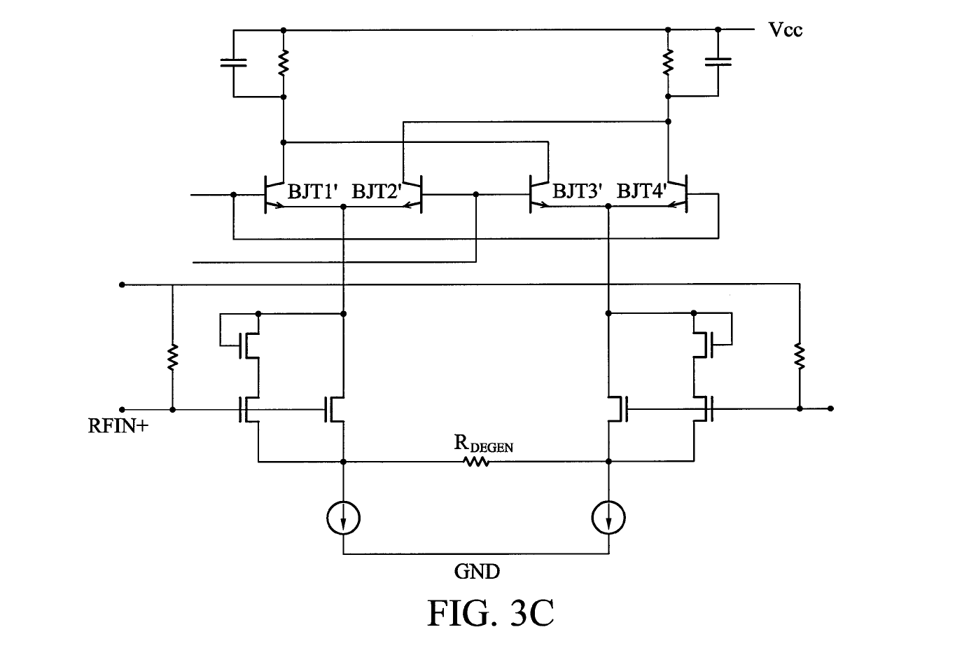

FIG. 3A is a circuit diagram of a double balanced mixer circuit according to another embodiment of the invention. The double balanced mixer circuit in FIG. 3A is similar to that in FIG. 2B and only differs in that the Gilbert cell mixer core 220 comprises differential pairs of PNP BJTs (BJT1-BJT2 and BJT3-BJT4). The collectors of the pairs of BJTs are connected to the fourth nodes 259 of the Gilbert cell mixer core 220. The bases of the pairs of BJTs receive the second differential input signal LO. The emitters of the BJT pair BJT1-BJT2 are connected to the third nodes 251 of the Gilbert cell mixer core 220. The emitters of the BJT pair BJT3-BJT4 are also connected to the third nodes 251 of the Gilbert cell mixer core 220.

FIG. 3B is a circuit diagram of a variant of the double balanced mixer circuit in FIG. 2B. The double balanced mixer circuit in FIG. 3B is similar to FIG. 2B and only differs in that the Gilbert cell mixer core 220 comprises differential pairs of N-type MOSFETs (SW1′-SW2′ and SW3′-SW4′). In addition, the first supply potential is the ground GND and the second supply potential is a power potential Vcc.

FIG. 3C is a circuit diagram of a variant of the double balanced mixer circuit in FIG. 3A. The double balanced mixer circuit in FIG. 3C is similar to FIG. 3A and only differs in that the Gilbert cell mixer core 220 comprises differential pairs of NPN BJTs (BJT1′-BJT2′ and BJT3′- BJT4′). In addition, the first supply potential is the ground GND and the second supply potential is a power potential Vcc.

While the invention has been described by way of example and in terms of preferred embodiment, it is to be understood that the invention is not limited thereto. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A sigma delta modulator, comprising:
a first active device network having a first node and a second node and comprising a first MOS transistor coupled therebetween; and
a second active device network having a first node and a second node respectively connected to the first and second nodes of the first active device network and comprising a second MOS transistor coupled between the first and second nodes and having a gate and a source respectively connected to a gate and a source of the first MOS transistor
wherein the first and second MOS transistors respectively operate in a saturation region and a triode region.

2. The transconductor as claimed in claim 1, wherein bias voltages of the first and second MOS transistors are provided by the same bias network.

3. The transconductor as claimed in claim 1,further comprising a voltage drop generator coupled between a drain of the second MOS transistor and the second nodes of the first and second active device networks and generating a voltage drop across the same.

4. The transconductor as claimed in claim 3, wherein the voltage drop generator comprises a diode with an anode coupled to the second nodes of the first and second active device networks and a cathode coupled to the drain of the second MOS transistor.

5. The transconductor as claimed in claim 3, wherein the voltage drop generator comprises a resistor coupled between the drain of the second MOS transistor and the second nodes of the first and second active device networks.

6. The transconductor as claimed in claim 3, wherein the voltage drop generator comprises a third MOS transistor with a drain coupled to the second nodes of the first and second active device networks and a source coupled to the drain of the second MOS transistor.

7. A mixer circuit, comprising:
a transconductor, comprising:
a first active device network having a first node and a second node and comprising a first MOS transistor coupled therebetween; and
a second active device network having a first node and a second node respectively connected to the first and second nodes of the first active device network and comprising a second MOS transistor coupled between the first and second nodes and having a gate and a source respectively connected to a gate and a source of the first MOS transistor;;
wherein the first and second MOS transistors respectively operate in a saturation region and a triode region, the gates of the first and second MOS transistors receive a first differential input signal and the first nodes of the first and second active device networks are coupled to a first supply voltage;
a Gilbert cell mixer core receiving a second differential input signal and having third nodes coupled to the second nodes of the first and second active device networks and fourth nodes providing a differential output signal; and
a pair of resistors respectively coupled between the fourth nodes of the Gilbert cell mixer core and a second supply voltage.

8. The mixer circuit as claimed in claim 7, further comprising a bias network providing a bias voltage to the first and second MOS transistors.

9. The mixer circuit as claimed in claim 7, further comprising a voltage drop generator coupled between a drain of the second MOS transistor and the second nodes of the first and second active device networks and generating a voltage drop across the same.

10. The mixer circuit as claimed in claim 9, wherein the voltage drop generator comprises a diode with an anode coupled to the second nodes of the first and second active device networks and a cathode coupled to the drain of the second MOS transistor.

11. The mixer circuit as claimed in claim 9, wherein the voltage drop generator comprises a resistor coupled between the drain of the second MOS transistor and the second nodes of the first and second active device networks.

12. The mixer circuit as claimed in claim 9, wherein the voltage drop generator comprises a third MOS transistor with a drain coupled to the second nodes of the first and second active device networks and a source coupled to the drain of the second MOS transistor.

13. The mixer circuit as claimed in claim 7, wherein the first and second supply voltages are the same.

14. The mixer circuit as claimed in claim 7, further comprising a bias network coupled between the first supply voltage and the transconductor.

15. The mixer circuit as claimed in claim 7, further comprising a degeneration impedance coupled between the first supply voltage and the transconductor.

16. The mixer circuit as claimed in claim 7, further comprising a pair of capacitors respectively connected with the resistors in parallel.

17. The mixer circuit as claimed in claim 7, wherein the Gilbert cell mixer core comprises differential pairs of MOS transistors.

18. The mixer circuit as claimed in claim 7, wherein the Gilbert cell mixer core comprises differential pairs of BJTs.
